(19) United States
(12) Patent Application Publication
(10) Pub. No.: US 2007/0189098 A1
(43) Pub. Date: Aug. 16, 2007

(54) Memory module with independently adjustable power supply

(76) Inventor: Jeff Hsieh, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/353,057

(22) Filed: Feb. 14, 2006

(51) Int. Cl. G11C 5/14

(52) U.S. Cl. 365/226

(57) ABSTRACT

A memory module with independently adjustable power supply is disconnected from a main board of a computer using the memory module, and includes a rectification circuit provided thereon. The rectification circuit is connected to a power supply of the computer, so that a supply voltage of 12V of the power supply is rectified by the rectification circuit and then supplied to the memory module, so that the memory module obtains stable and sufficient power. Wherein, the 12V voltage is input to the rectification circuit via a 12V 4-pin connector for a 1.44 MB floppy disk drive of the computer. The rectified power can be changed to different voltage values by a variable resistor in the rectification circuit to satisfy memories of different brands.

### FIELD OF THE INVENTION

The present invention relates to a memory module with independently adjustable power supply, and more particularly to a memory module that is independently powered to avoid unstable power supply caused by overloading of a computer and peripherals thereof.

### BACKGROUND OF THE INVENTION

Currently available personal computers and notebook computers use a double in-line memory module (DIMM) as a major memory capacity interface thereof. Being limited by the overall computer configuration, the memory could not always obtain reasonable supply of power. This problem has not been overcome up to date. With the development of computers with high operating speed and high memory capacity, it is necessary for the memory modules in the computers to have stable power supply, so that the memory is not affected by insufficient or unstable power supply when the computer and peripherals thereof are operating.

### SUMMARY OF THE INVENTION

A primary object of the present invention is to provide a memory module with independently adjustable power supply, so that the memory module can always obtain stable, sufficient, and independent power.

To achieve the above and other objects, the memory module according to the present invention has a power supply circuitry disconnected from a main board of a computer using the memory module, and includes a rectification circuit provided on the memory module. The rectification circuit is connected to a power supply of the computer, so that a supply voltage of 12V of the power supply is rectified by the rectification circuit and then supplied to the memory module, enabling the memory module to always obtain stable, sufficient, and independent power.

In the memory module of the present invention, the 12V voltage is input to the rectification circuit via a 12V 4-pin connector for a 1.44 MB floppy disk drive of the computer.

Moreover, in the memory module of the present invention, the rectification circuit includes a variable resistor for changing the rectified power to different voltage values to satisfy memories of different brands.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a block diagram of the present invention; and

FIG. 2 is a rectification circuit diagram of the present invention.

### DETAILED DESCRIPTION OF THE PREFERRED EMBODIMENTS

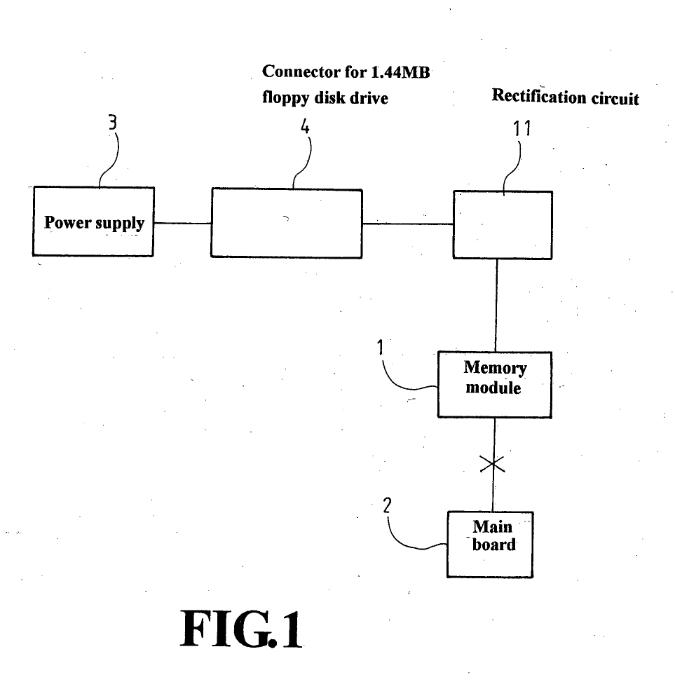

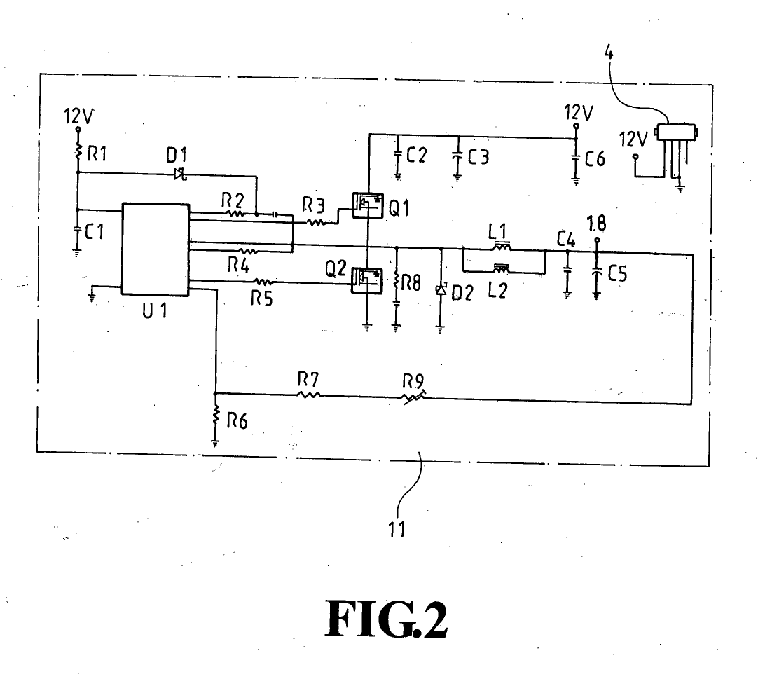

Please refer to FIGS. 1 and 2. In a memory module 1 according to the present invention, a power supply circuitry of the memory module 1 is disconnected from a main board 2 of a computer using the memory module 1, and a rectification circuit 11 is provided on a printed circuit board (PCB) having the memory module 1 mounted thereon. An input of the rectification circuit 11 is connected to a power supply 3 for the computer, so that a voltage of 12V supplied by the power supply 3 is rectified by the rectification circuit 11 to produce a power of 1.95V˜3.0V for supplying to the memory module 1. In this manner, the memory module 1 can always have sufficient and stable working voltage supplied thereto without being affected by the computer and other peripherals thereof.

In the present invention, the rectification circuit 11 may obtain the power of 12V via a 12V 4-pin connector 4 for a 1.44 MB floppy disk drive of the computer. In the rectification circuit 11, there are also included a voltage stabilizing IC (U1), two transistors (Q1) and (Q2), two parallelly connected inductances (L1) and (L2), and a variable resistor (R9). The parallelly connected inductances (L1) and (L2) reduce and stabilize the input 12V voltage. And, the reduced voltage is regulated by the variable resistor (R9) within the range from 1.95V to 3.0V, depending on the brand of memory being used.

With the memory module of the present invention, at least the following advantages are obtained:
1. Since the power supplied to the memory module may be discretionarily regulated according to the power requirement of different brands of memory, the memory module is more practical for use.
2. Since every piece of DIMM may have independently supplied power, the DIMM can always obtain sufficient power supply independent of the number of memories on the DIMM and the operating status of the computer.
3. For a personal computer or a notebook computer having an expanded memory, the number of DIMMs thereof is correspondingly increased to 2 or even 8 pieces. With the present invention, these DIMMs are not subject to unstable power supply due to overloading of the computer. Therefore, the memory module of the present invention is more reliable for use.
4. Since the memory module is not connected to the power supply on the main board, the memory module is not affected by a main board having poor or unqualified power supply. The compatibility of the memory module of the present invention with the main board is increased.

In brief, the memory module of the present invention can always independently obtain reliable and stable power supply to fully overcome the problem existed in the conventional memory module, and is therefore very practical for use.

What is claimed is:

1. A memory module with independently adjustable power supply, comprising a rectification circuit provided on a printed circuit board having said memory module mounted thereon, and a power supply circuitry being disconnected from a main board of a computer using said memory module; and said rectification circuit being connected to a power supply of said computer, so that power supplied from said power supply is rectified by said rectification circuit and then supplied to said memory module, enabling said memory module to obtain sufficient, stable, and independent power supply.

2. The memory module with independently adjustable power supply as claimed in claim 1, wherein said rectification circuit includes a variable resistor for regulating the rectified power to a desired voltage value depending on a brand of memory included in said memory modules.

3. The memory module with independently adjustable power supply as claimed in claim 1, wherein said rectification circuit is connected to a 12V 4-pin connector for a 1.44 MB floppy disk drive on the computer.
